(19) United States
(12) Patent Application Publication
(10) Pub. No.: US 2018/0174906 A1
(43) Pub. Date: Jun. 21, 2018

(54) SEMICONDUCTOR DEVICE AND METHOD OF MANUFACTURING THE SAME, AND STACKED SEMICONDUCTOR DEVICE

(71) Applicant: FUJITSU LIMITED, Kawasaki-shi (JP)

(72) Inventors: Hiroko TASHIRO, Ashigarakami (JP); Hideki KITADA, Atsugi (JP)

(73) Assignee: FUJITSU LIMITED, Kawasaki-shi (JP)

(21) Appl. No.: 15/822,593

(22) Filed: Nov. 27, 2017

(30) Foreign Application Priority Data
Dec. 16, 2016 (JP) 2016-244599

(51) Int. Cl. H01L 21/768; H01L 23/00; H01L 21/02; H01L 25/065

(52) U.S. Cl. CPC H01L 21/76898; H01L 24/12; H01L 24/16; H01L 21/02697; H01L 2924/10253; H01L 25/0657; H01L 2225/06513; H01L 2225/06541; H01L 21/76877

(57) ABSTRACT

A semiconductor device includes: a semiconductor substrate; a through silicon via which penetrates the semiconductor substrate; an insulating film which is provided between a side surface of the through silicon via and the semiconductor substrate; and a MOS transistor which is provided on the semiconductor substrate, wherein: the semiconductor substrate has a first crystal axis and a second crystal axis, and a propagation amount of stress occurring from the through silicon via is larger in a direction of the first crystal axis than in a direction of the second crystal axis; and the insulating film has a thickness in a direction of a diameter of the through silicon via being a thickness along the direction of the first crystal axis larger than a thickness along the direction of the second crystal axis.

### CROSS-REFERENCE TO RELATED APPLICATION

This application is based upon and claims the benefit of priority of the prior Japanese Patent Application No. 2016-244599, filed on Dec. 16, 2016, the entire contents of which are incorporated herein by reference.

### FIELD

The embodiments discussed herein are directed to a semiconductor device and a method of manufacturing the same, and a stacked semiconductor device.

### BACKGROUND

In recent years, for increasing the density of a semiconductor circuit and speeding up the signal transmission, a semiconductor device made by stacking semiconductor chips and electrically connecting the semiconductor chips by a through silicon via (TSV) penetrating a Si substrate is developed.

Patent Document 1: Japanese Laid-open Patent Publication No. 2011-192662

Patent Document 2: Japanese Laid-open Patent Publication No. 2006-108244

In the above-described semiconductor device, provision of the through silicon via causes stress around the through silicon via in the Si substrate and influences the characteristics of functional elements such as a transistor, a semiconductor circuit and the like provided on the Si substrate. Therefore, there is a keep-out zone (KOZ) where the functional elements cannot be arranged, around the through silicon via. Recently, higher integration of a semiconductor device is increasingly demanded, and narrowing the KOZ is desired for the higher integration.

### SUMMARY

In one aspect, a semiconductor device includes: a semiconductor layer; a through silicon via configured to penetrate the semiconductor layer; an insulating film configured to be provided between a side surface of the through silicon via and the semiconductor layer; and a functional element configured to be provided on the semiconductor layer, wherein: the semiconductor layer has a first crystal axis and a second crystal axis, and a propagation amount of stress occurring from the through silicon via is larger in a direction of the first crystal axis than in a direction of the second crystal axis; and the insulating film has a thickness in a direction of a diameter of the through silicon via being a thickness along the direction of the first crystal axis larger than a thickness along the direction of the second crystal axis.

In one aspect, a method of manufacturing a semiconductor device, the method includes: forming a first through hole configured to penetrate a semiconductor layer; filling the first through hole with an insulating material; forming a second through hole configured to penetrate the insulating material; and filling the second through hole with a conductive material to form a through silicon via, wherein: the semiconductor layer has a first crystal axis and a second crystal axis, and a propagation amount of stress occurring from the through silicon via is larger in a direction of the first crystal axis than in a direction of the second crystal axis; and an insulating film made of the insulating material has a thickness in a direction of a diameter of the through silicon via being a thickness along the direction of the first crystal axis larger than a thickness along the direction of the second crystal axis.

In one aspect, a stacked semiconductor device includes: a package substrate; and a semiconductor device provided on the package substrate, the semiconductor device including: a semiconductor layer; a through silicon via configured to penetrate the semiconductor layer; an insulating film configured to be provided between a side surface of the through silicon via and the semiconductor layer; and a functional element configured to be provided on the semiconductor layer, wherein: the semiconductor layer has a first crystal axis and a second crystal axis, and a propagation amount of stress occurring from the through silicon via is larger in a direction of the first crystal axis than in a direction of the second crystal axis; and the insulating film has a thickness in a direction of a diameter of the through silicon via being a thickness along the direction of the first crystal axis larger than a thickness along the direction of the second crystal axis.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a schematic sectional view illustrating the configuration of a semiconductor device according to a first embodiment;

FIG. 2 is a transverse sectional view illustrating a through silicon via and the appearance around an insulating film on a side surface of the through silicon via in the semiconductor device according to the first embodiment;

FIGS. 3A and 3B are transverse sectional views each illustrating the through silicon via and the appearance around the insulating film on the side surface of the through silicon via of the semiconductor device according to the first embodiment on the basis of comparison with a comparative example;

FIGS. 4A to 4F are schematic views illustrating steps of forming the through silicon via and the insulating film on the side surface of the through silicon via in the semiconductor device according to the first embodiment;

FIG. 5 is a schematic sectional view illustrating the configuration of a semiconductor device according to a modified example of the first embodiment;

FIG. 6 is a transverse sectional view illustrating a through silicon via and the appearance around an insulating film on a side surface of the through silicon via in the modified example of the first embodiment;

FIG. 7A and FIG. 7B are characteristic charts each illustrating a result obtained by performing simulation analysis on a stress distribution (Stress-YY) occurring in a Si substrate by the through silicon via of the semiconductor device according to the modified example of the first embodiment, on the basis of comparison with the comparative example;

FIG. 8 is a characteristic chart indicating one-dimensional Stress-YY values at Z=0 in FIGS. 7A and 7B for the modified example of the first embodiment and the comparative example;

FIGS. 9A to 9F are schematic views illustrating steps of forming the through silicon via and the insulating film on the side surface of the through silicon via in the semiconductor device according to the modified example of the first embodiment; and

FIG. 10 is a schematic sectional view illustrating the configuration of a stacked semiconductor device according to a second embodiment.

### DESCRIPTION OF EMBODIMENTS

Hereinafter, preferred embodiments will be explained in detail with reference to accompanying drawings.

### First Embodiment

This embodiment discloses a semiconductor device including a through silicon via penetrating a semiconductor substrate (semiconductor layer), and a method of manufacturing the same.

(Configuration of Semiconductor Device)

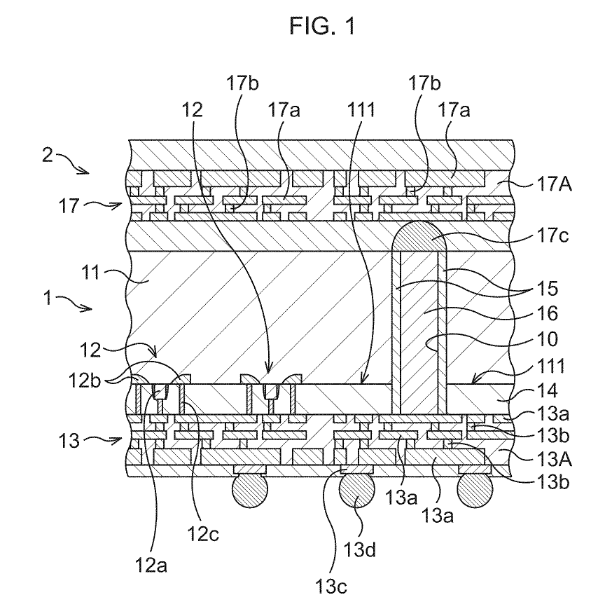

FIG. 1 is a schematic sectional view illustrating the configuration of the semiconductor device according to this embodiment.

The semiconductor device includes a first semiconductor chip 1 and a second semiconductor chip 2, the second semiconductor chip 2 being stacked on the first semiconductor chip 1.

The first semiconductor chip 1 includes a Si layer, here, a Si substrate 11, MOS transistors 12 formed on the Si substrate 11, a multilayer wiring layer 13 formed on the MOS transistors 12. Since the first semiconductor chip 1 is illustrated upside down here in FIG. 1, the MOS transistors 12 and the multilayer wiring layer 13 are provided in sequence under the Si substrate 11. The Si substrate 11 includes a surface having a plane index being a miller index set to (100).

An interlayer insulating film 14 is formed on the Si substrate 11, and a through hole 10 penetrating the Si substrate 11 and the interlayer insulating film 14 is formed. In the through hole 10, a through silicon via (TSV) 16 is formed via an insulating film 15. More specifically, the insulating film 15 is provided between a side surface of the through silicon via 16 and the Si substrate 11 and formed of, for example, a low dielectric constant (low-k) material such as a nano clustering silica (NSC), fluorine doped silicon glass (FSG) or the like or an organic insulating material such as an organic siloxane.

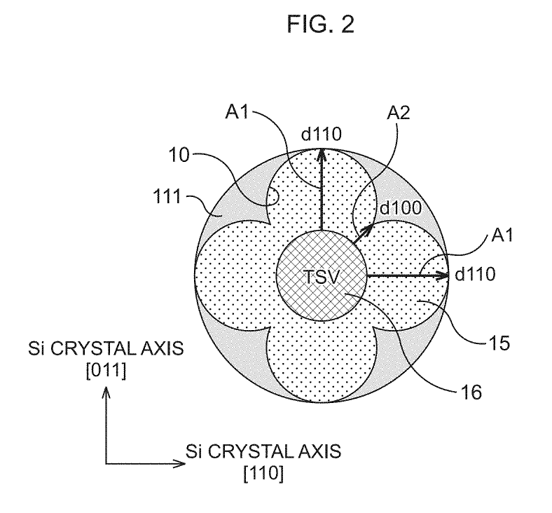

FIG. 2 is a transverse sectional view illustrating the through silicon via and the appearance around the insulating film on a side surface of the through silicon via.

The through silicon via 16 has a sectional shape in a direction of its diameter (transverse sectional shape) in an almost circular shape. The insulating film 15 has a transverse sectional shape formed in a four-leafed curved surface shape. The Si substrate 11 has a first crystal axis A1 having an orientation index of mirror indices of <110> and a second crystal axis A2 having an orientation index of <100>. In this embodiment, the insulating film 15 is made to have the transverse sectional shape formed in the four-leafed curved surface shape, and therefore has a thickness along the <110> direction of the first crystal axis A1 larger than the thickness along the <100> direction of the second crystal axis A2. In FIG. 2, a thickness d110 in a [110] direction of <110> (a thickness in a [011] direction is also d110) and a thickness d100 in the <100> direction of the insulating film 15 are illustrated, and d110 is larger than d100.

In the Si substrate 11 including the surface having a plane index of (100), the stress occurring around the through silicon via 16 is likely to spread more in the <110> direction of the first crystal axis A1 than in the <100> direction of the second crystal axis A2. In other words, the propagation amount of the stress occurring from the through silicon via 16 is larger in the <110> direction of the first crystal axis A1 than in the <100> direction of the second crystal axis A2.

Provision of the insulating film covering the side surface of the through silicon via enables suppression of propagation of the stress in the Si substrate. In this embodiment, the insulating film 15 is formed, according to the above-described propagation amount of the stress, to have the transverse sectional shape in the four-leafed shape so as to be thickest in the <110> direction of the first crystal axis A1 in which the propagation amount is large and thinnest in the <100> direction of the second crystal axis A2 in which the propagation amount is smaller than that in the <110> direction. By making the thickness of the insulating film 15 different between the <110> direction of the first crystal axis A1 and the <100> direction of the second crystal axis A2 as described above, the stress is efficiently suppressed. As a result, a KOZ 111 around the through silicon via 16 in the Si substrate 11 can be narrowed. This ensures that functional elements such as a transistor and the like can be arranged near the through silicon via 16 without deteriorating their characteristics, realizing further downsizing and higher integration of a semiconductor device.

The MOS transistor 12 being a functional element includes a gate electrode 12a and source/drain regions 12b, and is arranged on the outside of the KOZ 111. In this embodiment, the MOS transistor 12 closest to the through silicon via 16 is provided to be adjacent to the boundary of the KOZ 111 on the outside of the KOZ 111. The interlayer insulating film 14 is formed in a manner to cover (the gate electrodes 12a of) the MOS transistors 12.

The multilayer wiring layer 13 has wirings 13a stacked in a plurality layers in an interlayer insulating film 13A, in which the wiring 13a in a lower layer and the wiring 13a in an upper layer are electrically connected to each other via a via 13b. The wiring 13a in the lowermost layer (the uppermost layer in FIG. 1) is electrically connected to the MOS transistor 12 via a connection part 12c. To another wiring 13a in the lowermost layer, one end of the through silicon via 16 is electrically connected. The wiring 13a in the uppermost layer (the lowermost layer in FIG. 1) is provided with a solder bump 13d via a connection pad 13d.

The second semiconductor chip 2 includes a multilayer wiring layer 17.

The multilayer wiring layer 17 has wirings 17a stacked in a plurality layers in an interlayer insulating film 17A, in which the wiring 17a in a lower layer and the wiring 17a in an upper layer are electrically connected to each other via a via 17b. The wiring 17a in the lowermost layer is provided with a solder bump 17c, and the other end of the through silicon via 16 is electrically connected to the solder bump 17c. This semiconductor device employs a structure in which the multilayer wiring layer 13 of the first semiconductor chip 1 and the multilayer wiring layer 17 of the second semiconductor chip 2 are electrically connected to each other via the through silicon via 16.

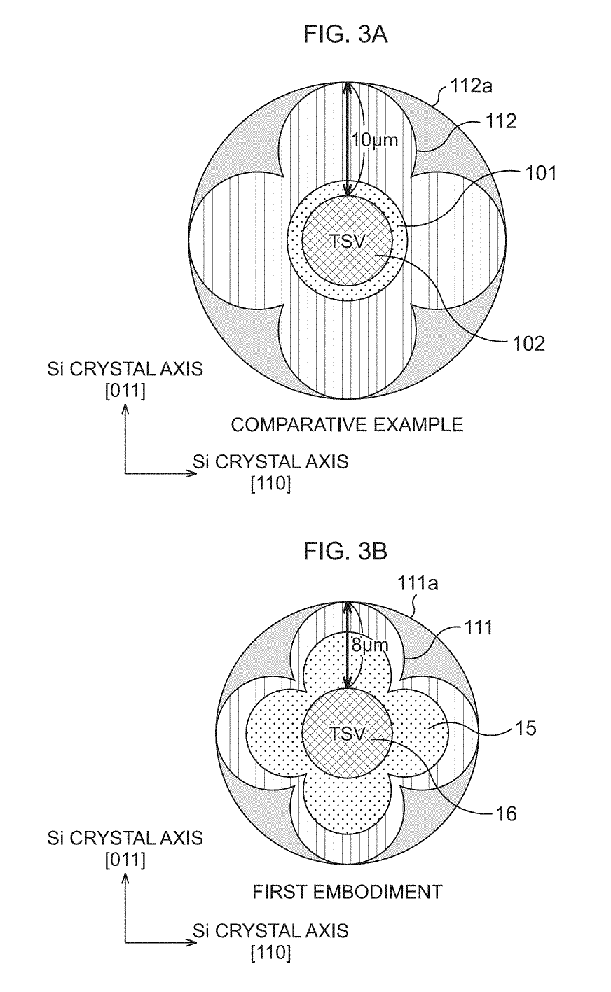

FIGS. 3A and 3B are transverse sectional views each illustrating the through silicon via and the appearance around the insulating film on the side surface of the through silicon via of the semiconductor device according to this embodiment on the basis of comparison with a comparative example, FIG. 3A illustrating the comparative example and FIG. 3B illustrating this embodiment.

In the comparative example, an insulating film 101 covering a side surface of a through silicon via 102 has a transverse sectional shape in a ring shape. In this embodiment, the insulating film 15 covering the side surface of the through silicon via 16 has the transverse sectional shape in the four-leafed shape, in which the <110> direction is the direction of the thickest portion in each of four leaves and the <100> direction is the direction of the thinnest portion. This thinnest portion is made to have, for example, the same thickness as that of the insulating film 101. A stress reference value of the KOZ is set to, for example, 110 MPa, and the KOZ in this embodiment is expressed as 111 and the KOZ in the comparative example is expressed as 112, as the KOZ found from the stress distribution by simulation. The KOZ 111 in this embodiment is narrower than the KOZ 112 in the comparative example. The maximum distance of the KOZ 111 from the through silicon via 16 is 8 μm, and the maximum distance of the KOZ 112 from the through silicon via 102 is 10 μm. Assuming that regions in circles with the distances as radii are KOZ 111a, 112a, the KOZ 111a in this embodiment decreases in area by 36% than the KOZ 112a in the comparative example.

The insulating film 15 in this embodiment has a transverse sectional area larger by a portion of four leaves than that of the insulating film 101 in the comparative example. By providing the insulating film 15, the electric capacity of the through silicon via 16 decreases as compared with the case where the insulating film 101 in the comparative example is provided. This realizes speed-up of signal transmission in addition to the downsizing and higher integration of a semiconductor device.

(Method of Manufacturing Semiconductor Device)

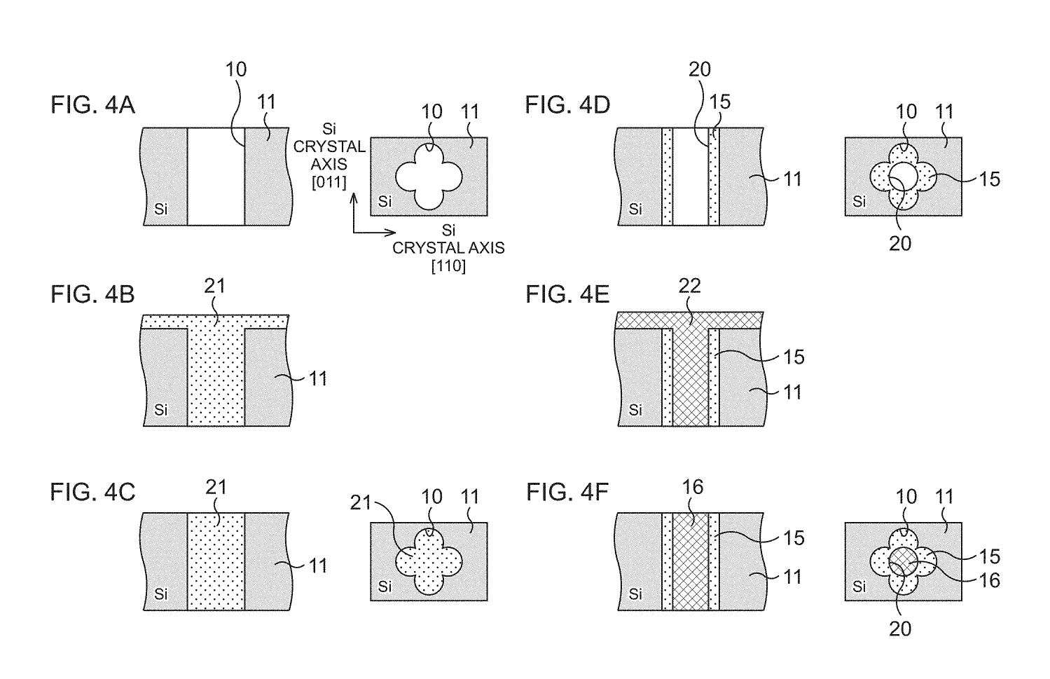

Next, the method of manufacturing the semiconductor device according to this embodiment will be explained. FIGS. 4A to 4F are schematic views illustrating steps of forming the through silicon via and the insulating film on the side surface of the through silicon via in the semiconductor device according to this embodiment. In FIG. 4A to FIG. 4F, left drawings are longitudinal sectional views and right drawings are transverse sectional views.

For the first semiconductor chip, first, the MOS transistor 12 is formed on the surface having the plane index of (100) of the Si substrate 11. The gate electrode 12a is pattern-formed on the Si substrate 11 via a predetermined gate insulating film, and the source/drain regions 12b are formed by ion implantation or the like of impurities of a predetermined conductivity type in a surface layer of the Si substrate 11 on both sides of the gate electrode 12a.

Subsequently, the interlayer insulating film 14 is formed in a manner to cover the gate electrode 12a. The connection part 12c bringing the gate electrode 12a and the source/drain regions 12b into conduction is formed through the interlayer insulating film 14.

Subsequently, the through silicon via 16 penetrating the Si substrate 11 and the interlayer insulating film 14 and the insulating film 15 on the side surface of the through silicon via 16 are formed.

First, as illustrated in FIG. 4A, the through hole (first through hole) 10 is formed in the Si substrate 11 and the interlayer insulating film 14. In detail, a resist mask is formed on the surface of the Si substrate 11, and etching is performed on the Si substrate 11 and the interlayer insulating film 14 using the resist mask. Thus, the through hole 10 is formed. In this embodiment, the through hole 10 is formed to have a transverse sectional shape in a four-leafed curved surface shape. The resist mask is removed by a wet treatment or asking treatment.

Next, as illustrated in FIG. 4B, the through hole 10 is filled with an insulating material 21.

In detail, the insulating material 21 is deposited on the Si substrate 11 to fill the through hole 10 by the CVD method or the like. As the insulating material 21, for example, a low dielectric constant (low-k) material such as a nano clustering silica (NSC), fluorine doped silicon glass (FSG) or the like or an organic insulating material such as an organic siloxane is used.

Next, as illustrated in FIG. 4C, the insulating material 21 on the Si substrate 11 is planarized.

In detail, the insulating material 21 on the Si substrate 11 is polished, for example, by the chemical-mechanical polishing (CMP). This removes the insulating material 21 on the Si substrate 11 so that the insulating material 21 having the planarized surface remains so as to fill only the inside of the through hole 10.

Next, as illustrated in FIG. 4D, a through hole 20 is formed in the insulating material 21.

In detail, a resist mask is formed on the surface of the Si substrate 11, and etching is performed on the insulating material 21 using the resist mask. Thus, the through hole (second through hole) 20 is formed. The through hole 20 is formed at a central portion of the insulating material 21 to have a transverse sectional shape in a circular shape. In this event, the insulating film 15 is formed on the side surface of the through hole 20. The insulating film 15 has a transverse sectional shape in a four-leafed curved surface shape in which the thickness along the <110> direction of the first crystal axis Al is largest and the thickness along the <100> direction of the second crystal axis A2 is smallest. The resist mask is removed by a wet treatment or asking treatment.

Next, as illustrated in FIG. 4E, the through hole 20 is filled with a conductive material 22.

In detail, the conductive material 22 is deposited on the Si substrate 11 to fill the through hole 20 by the plating method or the like. As the conductive material 22, for example, copper (Cu) is used.

Next, as illustrated in FIG. 4F, the conductive material 22 on the Si substrate 11 is planarized.

In detail, the conductive material 22 on the Si substrate 11 is polished, for example, by the CMP. This removes the conductive material 22 on the Si substrate 11 so that the conductive material 22 having the planarized surface remains so as to fill only the inside of the through hole 20. This conductive material 22 forms the through silicon via 16.

Subsequently, the multilayer wiring layer 13 is formed. The wirings 13a and the vias 13b constituting the layers of the multilayer wiring layer 13 are formed of, for example, Cu as a material. Another wiring 13a in the lowermost layer (the uppermost layer in FIG. 1) is electrically connected to the MOS transistor 12 via the connection part 12c. To the wiring 13a in the lowermost layer, one end of the through silicon via 16 is electrically connected. The wiring 13a in the uppermost layer (the lowermost layer in FIG. 1) is provided with the solder bump 13d via the connection pad 13d.

For the second semiconductor chip 2, the multilayer wiring layer 17 is formed. The wirings 17a and the vias 17b constituting the layers of the multilayer wiring layer 17 are formed of, for example, Cu as a material. The wiring 17a in the lowermost layer is provided with the solder bump 17c, and the other end of the through silicon via 16 is electrically connected to the solder bump 17c.

Thus, the semiconductor device is formed in which the multilayer wiring layer 13 of the first semiconductor chip 1 and the multilayer wiring layer 17 of the second semiconductor chip 2 are electrically connected to each other via the through silicon via 16.

As described above, according to this embodiment, the KOZ 111 in the Si substrate 11 provided with the through silicon via 16 is narrowed, thereby realizing the semiconductor device enabling further downsizing and higher integration.

### Modified Example

Hereinafter, a modified example of this embodiment will be explained. This modified example discloses a semiconductor device similar to that in this embodiment but is different from this embodiment in that the transverse sectional shape of the insulating film provided on the side surface of the through silicon via is different.

(Configuration of Semiconductor Device)

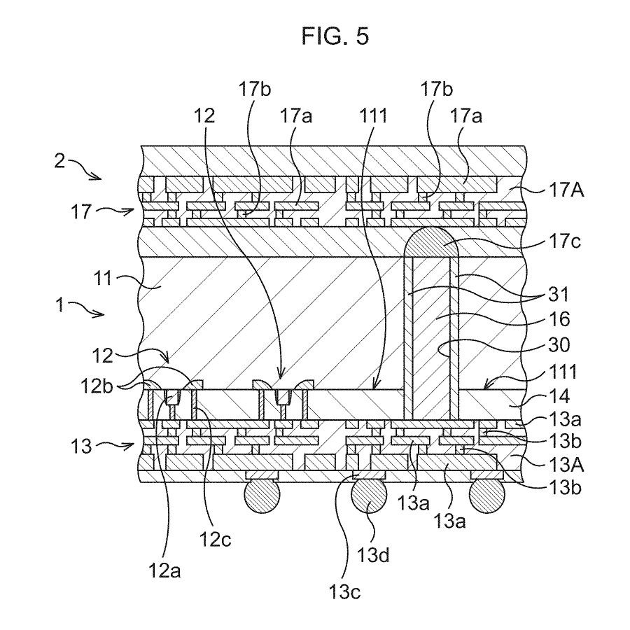

FIG. 5 is a schematic sectional view illustrating the configuration of the semiconductor device according to the modified example of this embodiment.

The semiconductor device includes a first semiconductor chip 1 and a second semiconductor chip 2 as in the first embodiment, the second semiconductor chip 2 being stacked on the first semiconductor chip 1.

The first semiconductor chip 1 includes a Si substrate 11, MOS transistors 12 formed on the Si substrate 11 (under the Si substrate 11 because the semiconductor chip 1 is upside down in FIG. 5, and this also applies to the following), a multilayer wiring layer 13 formed on the MOS transistors 12. The Si substrate 11 includes a surface having a plane index being a miller index set to (100).

An interlayer insulating film 14 is formed on the Si substrate 11, and a through hole 30 penetrating the Si substrate 11 and the interlayer insulating film 14 is formed. In the through hole 30, a through silicon via (TSV) 16 is formed via an insulating film 31. The insulating film 31 is formed of, for example, a low dielectric constant (low-k) material such as a nano clustering silica (NSC), fluorine doped silicon glass (FSG) or the like or an organic insulating material such as an organic siloxane.

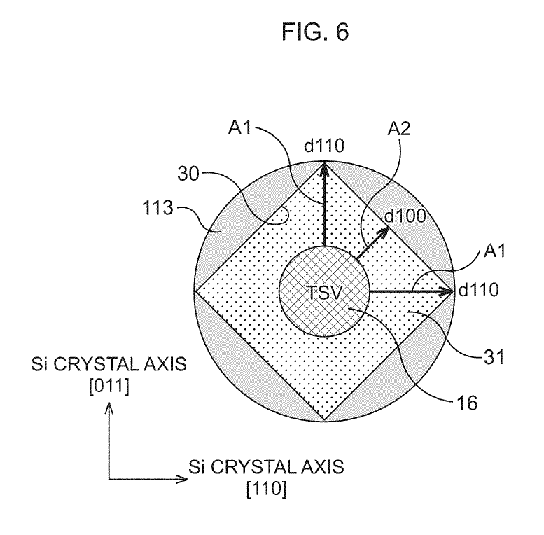

FIG. 6 is a transverse sectional view illustrating the through silicon via and the appearance around the insulating film on a side surface of the through silicon via.

The through silicon via 16 has a sectional shape (transverse sectional shape) in a direction of its diameter in an almost circular shape. The insulating film 31 has a transverse sectional shape formed in a rectangular shape (here, a regular tetragonal shape). The Si substrate 11 has a first crystal axis A1 having an orientation index of mirror indices of <110> and a second crystal axis A2 having an orientation index of <100>. In this embodiment, the insulating film 31 is made to have the transverse sectional shape formed in the rectangular shape, and therefore has a thickness along the <110> direction of the first crystal axis A1 larger than the thickness along the <100> direction of the second crystal axis A2. In FIG. 5, a thickness d110 in a [110] direction of <110> (a thickness in a [011] direction is also d110) and a thickness d100 in the <100> direction of the insulating film 31 are illustrated, and d110 is larger than d100.

In the Si substrate 11 including the surface having a plane index of (100), the stress occurring around the through silicon via 16 is likely to spread more in the <110> direction of the first crystal axis A1 than in the <100> direction of the second crystal axis A2. In other words, the propagation amount of the stress occurring from the through silicon via 16 is larger in the <110> direction of the first crystal axis A1 than in the <100> direction of the second crystal axis A2.

Provision of the insulating film covering the side surface of the through silicon via enables suppression of propagation of the stress in the Si substrate. In this embodiment, the insulating film 31 is formed, according to the above-described propagation amount of the stress, to have a rectangular shape so as to be thickest in the <110> direction of the first crystal axis A1 in which the propagation amount is large and thinnest in the <100> direction of the second crystal axis A2 in which the propagation amount is smaller than that in the <110> direction. By making the thickness of the insulating film 31 different between the <110> direction of the first crystal axis A1 and the <100> direction of the second crystal axis A2 as described above, the stress is efficiently suppressed, thereby making it possible to narrow the KOZ 111 around the through silicon via 16 in the Si substrate 11. This ensures that functional elements such as a transistor and the like can be arranged near the through silicon via 16 without deteriorating their characteristics, realizing further downsizing and higher integration of a semiconductor device.

The insulating film 31 in this modified example has a transverse sectional area larger than that of the insulating film 101 in the comparative example explained in the first embodiment. By providing the insulating film 31, the electric capacity of the through silicon via 16 decreases as compared with the case where the insulating film 101 in the comparative example is provided. This realizes speed-up of signal transmission in addition to the downsizing and higher integration of a semiconductor device.

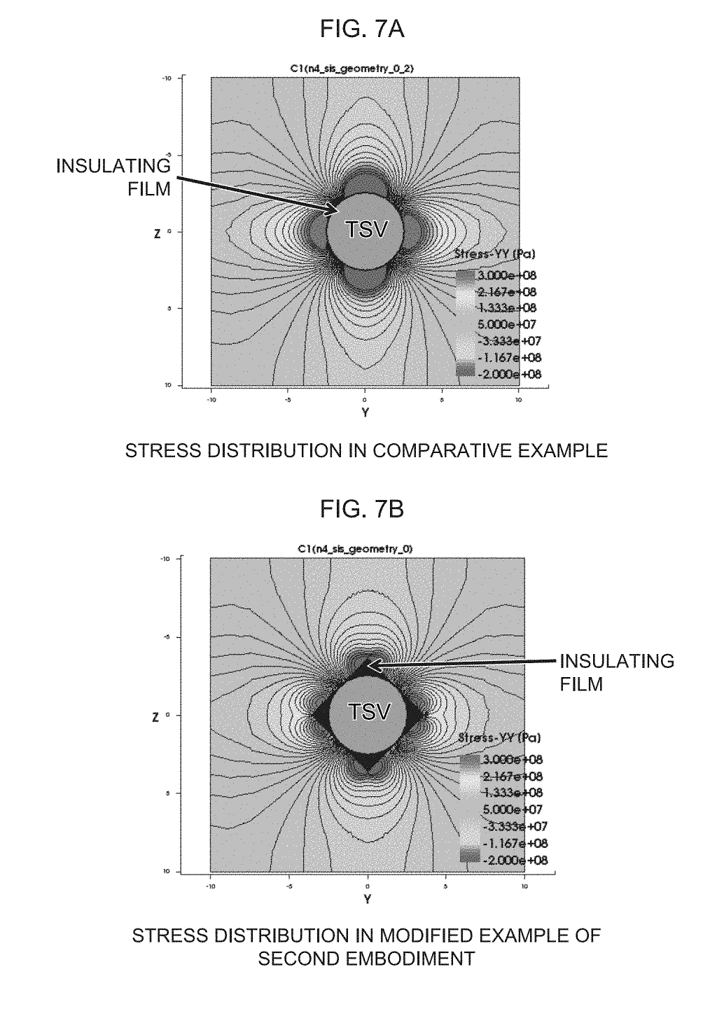

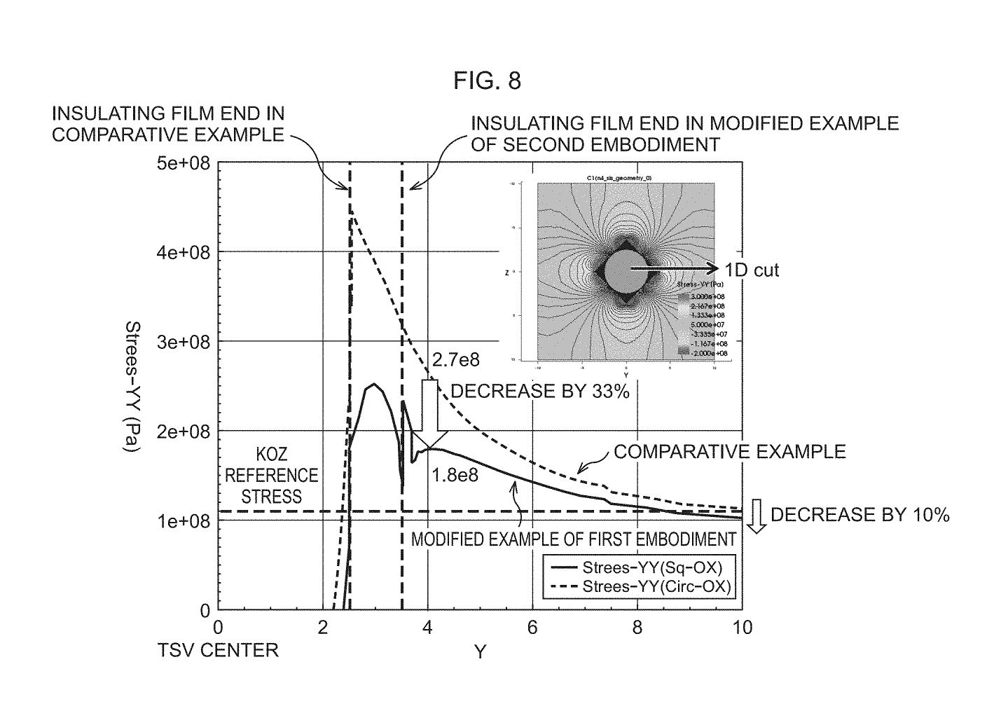

FIG. 7A and FIG. 7B are characteristic charts each illustrating a result obtained by performing simulation analysis on the stress distribution (Stress-YY) occurring in the Si substrate by the through silicon via of the semiconductor device according to this modified example, on the basis of comparison with the comparative example. FIG. 7A illustrates the comparative example, and FIG. 7B illustrates this modified example. FIG. 8 is a characteristic chart indicating one-dimensional Stress-YY values at Z=0 in FIGS. 7A and 7B for this modified example and the comparative example.

In the semiconductor device in the comparative example, the insulating film having the transverse sectional shape in the ring shape is formed in a manner to cover the side surface of the through silicon via. Each of this modified example and the comparative example is provided with a through silicon via having a diameter of 5 μm, and the residual stress when the temperature was changed from 250° C. to 25° C. was analyzed in the simulation.

As illustrated in FIG. 7A and FIG. 7B, it is found that the stress value is small, near the vertex of the rectangle (regular tetragon) of the insulating film in this modified example, as compared with the comparative example. As illustrated in FIG. 8, a decrease in stress value of about 33% nearby the insulating film and a decrease in stress value of about 10% near 10 μm from the center of the through silicon via in this modified example as compared with the comparative example can be confirmed.

(Method of Manufacturing Semiconductor Device)

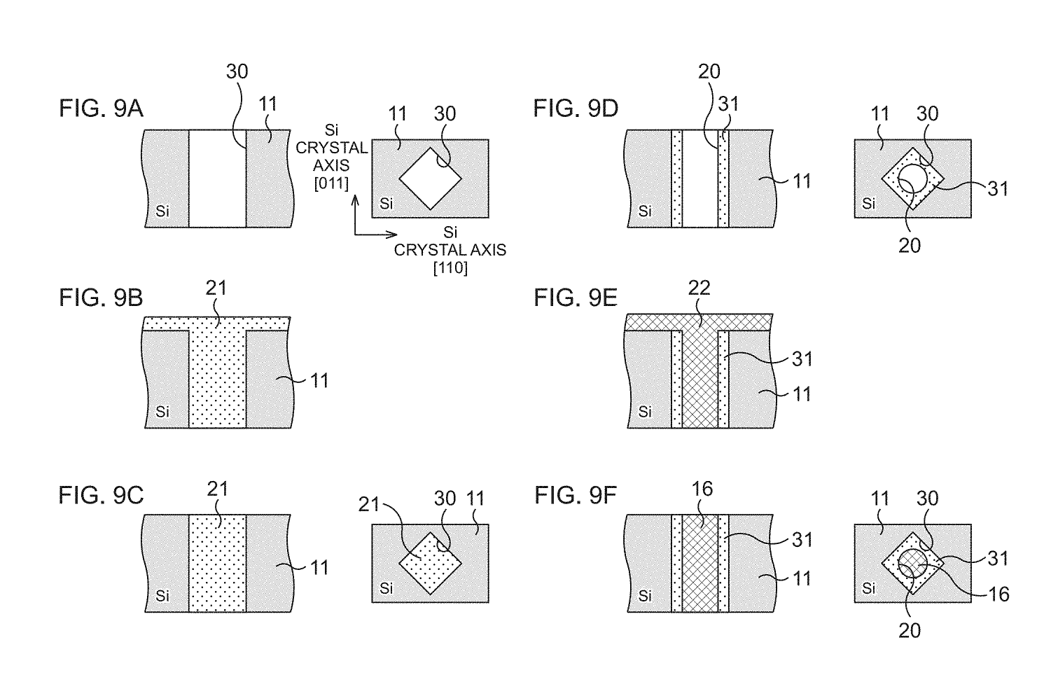

Next, the method of manufacturing the semiconductor device according to this modified example will be explained. FIGS. 9A to 9F are schematic views illustrating steps of forming the through silicon via and the insulating film on the side surface of the through silicon via in the semiconductor device according to this modified example. In FIG. 9A to FIG. 9F, left drawings are longitudinal sectional views and right drawings are transverse sectional views.

For the first semiconductor chip, first, the MOS transistor 12 is formed, as in the first embodiment, on the surface having the plane index of (100) of the Si substrate 11.

Subsequently, the interlayer insulating film 14 is formed and the connection part 12c is formed through the interlayer insulating film 14 as in first embodiment.

Subsequently, the through silicon via 16 penetrating the Si substrate 11 and the interlayer insulating film 14 and the insulating film 31 on the side surface of the through silicon via 16 are formed.

First, as illustrated in FIG. 9A, the through hole (first through hole) 30 is formed in the Si substrate 11 and the interlayer insulating film 14. In detail, a resist mask is formed on the surface of the Si substrate 11, and etching is performed on the Si substrate 11 and the interlayer insulating film 14 using the resist mask. Thus, the through hole 30 is formed. In this modified example, the through hole 30 is formed to have a transverse sectional shape in a rectangular shape. The resist mask is removed by a wet treatment or asking treatment.

Next, as illustrated in FIG. 9B, the through hole 30 is filled with an insulating material 21.

In detail, the insulating material 21 is deposited on the Si substrate 11 to fill the through hole 30 by the CVD method or the like. As the insulating material 21, for example, a low dielectric constant (low-k) material such as a nano clustering silica (NSC), fluorine doped silicon glass (FSG) or the like or an organic insulating material such as an organic siloxane is used.

Next, as illustrated in FIG. 9C, the insulating material 21 on the Si substrate 11 is planarized.

In detail, the insulating material 21 on the Si substrate 11 is polished, for example, by the CMP. This removes the insulating material 21 on the Si substrate 11 so that the insulating material 21 having the planarized surface remains so as to fill only the inside of the through hole 30.

Next, as illustrated in FIG. 9D, a through hole 20 is formed in the insulating material 21.

In detail, a resist mask is formed on the surface of the Si substrate 11, and etching is performed on the insulating material 21 using the resist mask. Thus, the through hole (second through hole) 20 is formed. The through hole 20 is formed at a central portion of the insulating material 21 to have a transverse sectional shape in a circular shape. In this event, the insulating film 31 is formed on the side surface of the through hole 20. The insulating film 31 has a transverse sectional shape in a rectangular shape in which the thickness along the <110> direction of the first crystal axis A1 is largest and the thickness along the <100> direction of the second crystal axis A2 is smallest. The resist mask is removed by a wet treatment or asking treatment.

Next, as illustrated in FIG. 9E, the through hole 20 is filled with a conductive material 22.

In detail, the conductive material 22 is deposited on the Si substrate 11 to fill the through hole 20 by the plating method or the like. As the conductive material 22, for example, Cu is used.

Next, as illustrated in FIG. 9F, the conductive material 22 on the Si substrate 11 is planarized.

In detail, the conductive material 22 on the Si substrate 11 is polished, for example, by the CMP. This removes the conductive material 22 on the Si substrate 11 so that the conductive material 22 having the planarized surface remains so as to fill only the inside of the through hole 20. This conductive material 22 forms the through silicon via 16

Subsequently, the multilayer wiring layer 13 is formed as in the first embodiment.

For the second semiconductor chip 2, the multilayer wiring layer 17 is formed as in the first embodiment.

Thus, the semiconductor device is formed in which the multilayer wiring layer 13 of the first semiconductor chip 1 and the multilayer wiring layer 17 of the second semiconductor chip 2 are electrically connected to each other via the through silicon via 16.

As described above, according to this modified example, the KOZ 111 in the Si substrate 11 provided with the through silicon via 16 is narrowed, thereby realizing the semiconductor device enabling further downsizing and higher integration.

### Second Embodiment

This embodiment discloses a stacked semiconductor device in which a semiconductor device including a through silicon via penetrating a semiconductor substrate (semiconductor layer) is mounted on a package substrate.

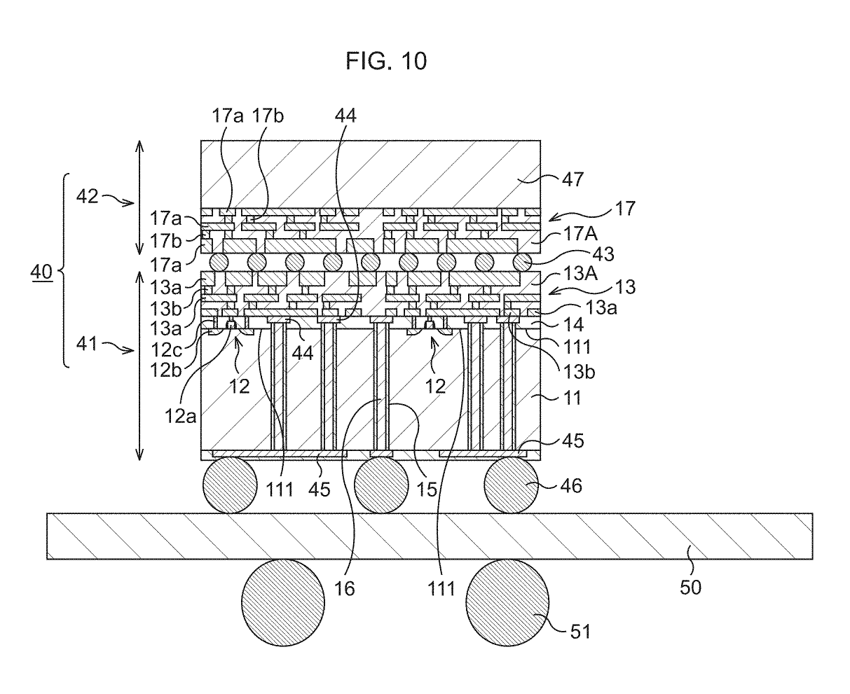

FIG. 10 is a schematic sectional view illustrating the configuration of the stacked semiconductor device according to this embodiment. Note that the same components and the like as those of the semiconductor device according to the first embodiment are denoted by the same numerals and detailed description thereof will be omitted.

This stacked semiconductor device includes a semiconductor device 40 mounted on a package substrate 50. The semiconductor device 40 is the semiconductor device according to the first embodiment or the modified example, and the semiconductor device according to the first embodiment is exemplified in this embodiment. The semiconductor device 40 is electrically connected onto the package substrate 50 via solder bumps 46, and solder bumps 51 are provided on the rear surface of the package substrate 50. The solder bump 46 is a so-called C4 bump having a diameter of about 150 μm to about 180 μm. The solder bump 51 is a so-called BGA having a diameter of about 500 μm.

The semiconductor device 40 includes a first semiconductor chip 41 and a second semiconductor chip 42, the second semiconductor chip 42 being stacked on the first semiconductor chip 41.

The first semiconductor chip 41 includes a Si substrate 11, MOS transistors 12 formed on the Si substrate 11, and a multilayer wiring layer 13 formed on the MOS transistors 12. The Si substrate 11 includes a surface having a plane index being a miller index set to (100).

An interlayer insulating film 14 is formed on the Si substrate 11, and a through hole 10 penetrating the Si substrate 11 and the interlayer insulating film 14 is formed. In the through hole 10, a through silicon via 16 is formed via an insulating film 15.

As described in the first embodiment, the insulating film 15 is formed to have a transverse sectional shape in a four-leafed shape so as to be thickest in the <110> direction of the first crystal axis in which the propagation amount of stress in the Si substrate 11 is large and thinnest in the <100> direction of the second crystal axis in which the propagation amount is smaller than that in the <110> direction. By making the thickness of the insulating film 15 different between the <110> direction of the first crystal axis and the <100> direction of the second crystal axis as described above, the stress is efficiently suppressed. As a result, a KOZ 111 around the through silicon via 16 in the Si substrate 11 can be narrowed. This ensures that functional elements such as a transistor and the like can be arranged near the through silicon via 16 without deteriorating their characteristics, realizing further downsizing and higher integration of a semiconductor device.

The through silicon via 16 has one end electrically connected to a connection pad 44 provided under the multilayer wiring layer 13 and the other end electrically connected to a connection pad 45 provided under the Si substrate 11. The connection pad 45 and the package substrate 50 are electrically connected to each other via the solder bump 46. With this structure, the multilayer wiring layer 13 of the first semiconductor chip 41 and the package substrate 50 are electrically connected to each other via the through silicon via 16 and so on.

The second semiconductor chip 42 includes a multilayer wiring layer 17 on a Si substrate 47 (under the Si substrate 47 because the semiconductor chip 42 is upside down in FIG. 10).

The multilayer wiring layer 13 of the first semiconductor chip 41 and the multilayer wiring layer 17 of the second semiconductor chip 42 are electrically connected to each other via solder bumps 43. The solder bump 43 is a so-called micro bump having a diameter of about 20 μm to about 30 μm.

As described above, according to this embodiment, the KOZ 111 in the Si substrate 11 provided with the through silicon via 16 is narrowed, thereby realizing the stacked semiconductor device enabling further downsizing and higher integration.

In the above-described first and second embodiments and modified example, the case where the Si substrate is used as the semiconductor substrate (semiconductor layer) of the semiconductor device and the through silicon via penetrating the Si substrate is provided is explained, but the present invention is not limited to this form. The present invention is also applicable, for example, to other semiconductor substrates (semiconductor layers) in place of the Si substrate, such as a GaN substrate, a GaAs substrate, an InP substrate, a SiGe substrate and the like. Also in the cases of using those semiconductor substrates, the semiconductor substrate (semiconductor layer) has the first crystal axis and the second crystal axis in which the propagation amount of the stress occurring from the through silicon via is larger in the first crystal axis than in the second crystal axis. Hence, the insulating film in one kind of form selected from the first and second embodiments and the modified example is provided on the side surface of the through silicon via. This insulating film has a thickness in a direction of the diameter of the through silicon being a thickness along the direction of the first crystal axis larger than the thickness along the direction of the second crystal axis. Employing this configuration narrows the KOZ in the semiconductor substrate provided with the through silicon via, realizing a semiconductor device enabling further downsizing and higher integration.

Note that the first crystal axis and the second crystal axis can be found by the X-ray diffraction (XRD) method, the Raman spectrometry or the like for the Si substrates in the first and second embodiments and the modified example and the above-described semiconductor substrates.

In one aspect, a semiconductor device and a stacked semiconductor device are realized which enable further downsizing and higher integration by narrowing a KOZ in a semiconductor layer provided with a through silicon via.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor device comprising:
a semiconductor layer;
a through silicon via configured to penetrate the semiconductor layer;
an insulating film configured to be provided between a side surface of the through silicon via and the semiconductor layer; and
a functional element configured to be provided on the semiconductor layer, wherein:
the semiconductor layer has a first crystal axis and a second crystal axis, and a propagation amount of stress occurring from the through silicon via is larger in a direction of the first crystal axis than in a direction of the second crystal axis; and
the insulating film has a thickness in a direction of a diameter of the through silicon via being a thickness along the direction of the first crystal axis larger than a thickness along the direction of the second crystal axis.

2. The semiconductor device according to claim 1, wherein:
the semiconductor layer is a Si layer including a surface having a plane index of (100); and
an orientation index in the direction of the first crystal axis is <110> and an orientation index in the direction of the second crystal axis is <100>.

3. The semiconductor device according to claim 1, wherein the insulating film has a sectional shape in the direction of the diameter of the through silicon via formed in a four-leafed curved surface shape.

4. The semiconductor device according to claim 1, wherein the insulating film has a sectional shape in the direction of the diameter of the through silicon via formed in a rectangular shape.

5. A method of manufacturing a semiconductor device, the method comprising:
forming a first through hole configured to penetrate a semiconductor layer;
filling the first through hole with an insulating material;
forming a second through hole configured to penetrate the insulating material; and
filling the second through hole with a conductive material to form a through silicon via, wherein:
the semiconductor layer has a first crystal axis and a second crystal axis, and a propagation amount of stress occurring from the through silicon via is larger in a direction of the first crystal axis than in a direction of the second crystal axis; and
an insulating film made of the insulating material has a thickness in a direction of a diameter of the through silicon via being a thickness along the direction of the first crystal axis larger than a thickness along the direction of the second crystal axis.

6. The method of manufacturing a semiconductor device according to claim 5, wherein:
the semiconductor layer is a Si layer including a surface having a plane index of (100); and
an orientation index in the direction of the first crystal axis is <110> and an orientation index in the direction of the second crystal axis is <100>.

7. The method of manufacturing a semiconductor device according to claim 5, wherein the insulating film has a sectional shape in the direction of the diameter of the through silicon via formed in a four-leafed curved surface shape.

8. The method of manufacturing a semiconductor device according to claim 5, wherein the insulating film has a sectional shape in the direction of the diameter of the through silicon via formed in a rectangular shape.

9. A stacked semiconductor device comprising:
a package substrate; and
a semiconductor device provided on the package substrate,
the semiconductor device comprising:
a semiconductor layer;
a through silicon via configured to penetrate the semiconductor layer;
an insulating film configured to be provided between a side surface of the through silicon via and the semiconductor layer; and
a functional element configured to be provided on the semiconductor layer, wherein:
the semiconductor layer has a first crystal axis and a second crystal axis, and a propagation amount of stress occurring from the through silicon via is larger in a direction of the first crystal axis than in a direction of the second crystal axis; and
the insulating film has a thickness in a direction of a diameter of the through silicon via being a thickness along the direction of the first crystal axis larger than a thickness along the direction of the second crystal axis.

10. The stacked semiconductor device according to claim 9, wherein:
the semiconductor layer is a Si layer including a surface having a plane index of (100); and
an orientation index in the direction of the first crystal axis is <110> and an orientation index in the direction of the second crystal axis is <100>.
